(19) United States
(12) Patent Application Publication
(10) Pub. No.: US 2026/0293490 A1
(43) Pub. Date: Sep. 24, 2026

(54) DISPLAY APPARATUS, ELECTRONIC APPARATUS, AND METHOD OF MANUFACTURING DISPLAY APPARATUS

(71) Applicant: Samsung Display Co., Ltd., Yongin-si (KR)

(72) Inventors: Seoulki Lee, Yongin-si (KR); Joongu Lee, Yongin-si (KR); Hwi Kim, Yongin-si (KR); Jihee Son, Yongin-si (KR)

(21) Appl. No.: 19/549,835

(22) Filed: Feb. 25, 2026

(30) Foreign Application Priority Data
Mar. 20, 2025 (KR) 10-2025-0036211

(51) Int. Cl. H10K 59/80; H10K 59/12; H10K 71/60; H10K 102/00; H10K 102/10

(52) U.S. Cl. CPC H10K 59/80517; H10K 59/1201; H10K 59/80518; H10K 71/60; H10K 2102/101; H10K 2102/351

(57) ABSTRACT

A display apparatus includes: a substrate; a pixel electrode including a lower transparent conductive oxide layer on the substrate, a reflective layer on the lower transparent conductive oxide layer, an upper transparent conductive oxide layer on the reflective layer, and a getter layer between the lower transparent conductive oxide layer and the reflective layer; an intermediate layer on the pixel electrode and including an emission layer; and an opposite electrode on the intermediate layer, wherein the getter layer includes at least one of ytterbium (Yb) or magnesium (Mg).

### CROSS-REFERENCE TO RELATED APPLICATION

The present application claims priority to and the benefit of Korean Patent Application No. 10-2025-0036211, filed on Mar. 20, 2025, in the Korean Intellectual Property Office, the entire disclosure of which is incorporated herein by reference.

### BACKGROUND

### 1. Field

One or more embodiments of the present disclosure relate to a display apparatus, an electronic apparatus, and a method of manufacturing a display apparatus.

### 2. Description of the Related Art

As the information-oriented society develops, portable electronic apparatuses such as mobile phones, tablet PCs, wearable devices, and/or the like have gained popularity and become widely used due to their convenience and functionality.

Such portable electronic apparatuses may include a display apparatus that provides various functions, for example, displaying visual information including images and/or video to a user. Recently, as components for driving display apparatuses have become smaller (increasingly miniaturized), the display area has come to occupy a larger portion of the electronic apparatus. For example, full-screen display apparatuses have been developed. Additionally, significant efforts have been made to develop display structures that may be bent from a flat state to a certain angle, thereby enhancing device flexibility and usability.

### SUMMARY

One or more aspects of embodiments of the present disclosure are directed toward a display apparatus that implements a high-quality image, an electronic apparatus including the display apparatus, and a method of manufacturing the display apparatus. However, aspects of the present disclosure are not limited to thereto.

Additional aspects will be set forth in part in the description which follows and, in part, will be apparent from the description, or may be learned by practice of the presented embodiments of the disclosure.

According to one or more embodiments of the present disclosure, a display apparatus includes: a substrate; a pixel electrode including a lower transparent conductive oxide layer on the substrate, a reflective layer on the lower transparent conductive oxide layer, an upper transparent conductive oxide layer on the reflective layer, and a getter layer between (e.g., arranged between) the lower transparent conductive oxide layer and the reflective layer; an intermediate layer on the pixel electrode and including an emission layer; and an opposite electrode on the intermediate layer, wherein the getter layer may include at least one of ytterbium (Yb) or magnesium (Mg).

In one or more embodiments, the lower transparent conductive oxide layer may be between (e.g., arranged between) the substrate and the getter layer, and the upper transparent conductive oxide layer may be between (e.g., arranged between) the reflective layer and the intermediate layer.

In one or more embodiments, a distance between the intermediate layer and the getter layer may be greater than a distance between the intermediate layer and the reflective layer.

In one or more embodiments, a thickness of the getter layer may be smaller than a thickness of the reflective layer.

In one or more embodiments, the thickness of the getter layer may be smaller than a thickness of the lower transparent conductive oxide layer.

In one or more embodiments, the reflective layer may include at least one of silver (Ag), magnesium (Mg), aluminum (Al), platinum (Pt), palladium (Pd), gold (Au), nickel (Ni), neodymium (Nd), iridium (Ir), or chromium (Cr).

In one or more embodiments, each of the lower transparent conductive oxide layer and the upper transparent conductive oxide layer may include at least one of indium tin oxide, indium zinc oxide, zinc oxide, indium oxide, indium gallium oxide, indium gallium zinc oxide, gallium zinc oxide, or aluminum zinc oxide.

According to one or more embodiments of the present disclosure, an electronic apparatus includes a display module including a display apparatus, and a processor configured to provide an image data signal and an input control signal to the display module, wherein the display apparatus may include: a substrate; a pixel electrode including a lower transparent conductive oxide layer on the substrate, a reflective layer on the lower transparent conductive oxide layer, an upper transparent conductive oxide layer on the reflective layer, and a getter layer between (e.g., arranged between) the lower transparent conductive oxide layer and the reflective layer; an intermediate layer on the pixel electrode and including an emission layer; and an opposite electrode on the intermediate layer, wherein the getter layer includes at least one of ytterbium (Yb) or magnesium (Mg).

In one or more embodiments, the lower transparent conductive oxide layer may be between (e.g., arranged between) the substrate and the getter layer, and the upper transparent conductive oxide layer may be between (e.g., arranged between) the reflective layer and the intermediate layer.

In one or more embodiments, a thickness of the getter layer may be smaller than a thickness of the reflective layer.

In one or more embodiments, the thickness of the getter layer may be smaller than a thickness of the lower transparent conductive oxide layer.

In one or more embodiments, the electronic apparatus may be any one selected from among a mobile phone, a tablet personal computer, a laptop, a television, a desk monitor, smart glasses, a head-mounted display, a smart watch, and a vehicle electronic apparatus.

According to one or more embodiments of the present disclosure, a method of manufacturing a display apparatus includes, on a substrate, sequentially stacking a lower transparent conductive oxide layer, a getter layer, a reflective layer, and an upper transparent conductive oxide layer, to form a pixel electrode, forming an intermediate layer including an emission layer on the pixel electrode, and forming an opposite electrode on the intermediate layer, wherein the getter layer may include at least one of ytterbium or magnesium.

In one or more embodiments, the getter layer may be arranged between the lower transparent conductive oxide layer and the reflective layer, the lower transparent conductive oxide layer may be arranged between the substrate and the getter layer, and the upper transparent conductive oxide layer may be arranged between the reflective layer and the intermediate layer.

In one or more embodiments, the getter layer may be formed by a sputtering process.

In one or more embodiments, a thickness of the getter layer may be formed to be smaller than a thickness of the reflective layer.

In one or more embodiments, the thickness of the getter layer may be formed to be smaller than a thickness of the lower transparent conductive oxide layer.

For example, the embodiments described herein provide a display apparatus and associated manufacturing method that enhance image quality and device reliability by incorporating a getter layer between transparent conductive oxide and reflective layers within the pixel electrode structure. The inclusion of materials such as ytterbium and/or magnesium in the getter layer contributes to improved performance by mitigating degradation mechanisms, such as moisture and/or oxygen ingress, that may adversely affect emission efficiency and longevity. These structures are applicable across a wide range of electronic apparatuses, including mobile and/or wearable technologies, and support the development of high-resolution, flexible, and durable display solutions.

### BRIEF DESCRIPTION OF DRAWINGS

The accompanying drawings are included to provide a further understanding of the present disclosure and are incorporated in and constitute a part of the present disclosure. The drawings illustrate embodiments of the present disclosure and, together with the description, serve to explain principles of the present disclosure. The above and other aspects, features, and advantages of certain embodiments of the disclosure will be more apparent from the following description taken in conjunction with the accompanying drawings, in which:

FIG. 1 is a schematic plan view of a display apparatus according to one or more embodiments of the present disclosure;

FIG. 2 is an equivalent circuit diagram of a pixel included in a display apparatus according to one or more embodiments of the present disclosure;

FIG. 3 is a schematic cross-sectional view of a display apparatus, taken along the line I-I' of FIG. 1, according to one or more embodiments of the present disclosure;

FIG. 4 is a schematic cross-sectional view of a pixel electrode of a display apparatus according to one or more embodiments of the present disclosure;

FIG. 5 is a block diagram of an electronic apparatus according to one or more embodiments of the present disclosure; and

FIG. 6 illustrates schematic views of an electronic apparatus according to one or more embodiments of the present disclosure.

### DETAILED DESCRIPTION

Reference will now be made in more detail to one or more embodiments, examples of which are illustrated in the accompanying drawings, wherein like reference numerals refer to like elements throughout the disclosure, and duplicative descriptions thereof may not be provided. In this regard, the presented embodiments may have different forms and should not be construed as being limited to the descriptions set forth herein. Accordingly, embodiments of the present disclosure are merely described in more detail, by referring to the drawings, to explain aspects of the present disclosure. As used herein, the term "and/or" or “or” may include any and all combinations of one or more of the associated listed items. Throughout the disclosure, the expressions such as “at least one of,” “one of,” and “selected from,” when preceding a list of elements, modify the entire list of elements and do not modify the individual elements of the list. For example, "at least one of a, b, or c", “at least one selected from among a, b, and c”, "at least one selected from among a to c", and/or the like, may indicate only a, only b, only c, both (e.g., simultaneously) a and b, both (e.g., simultaneously) a and c, both (e.g., simultaneously) b and c, all of a, b, and c, or variations thereof.

Hereinafter, one or more embodiments will be described in more detail with reference to the accompanying drawings. When describing with reference to the drawings, identical or corresponding components are given the same or like drawing reference numerals/reference letters, and redundant descriptions thereof may not be repeated for conciseness.

In the present disclosure, the terms "first", "second," and/or the like are not used in a limiting sense but are used to distinguish one component from another. Thus, a first element described could also be termed as a second or third element without departing from the spirit and scope of the disclosure.

According to one or more embodiments of the present disclosure, an x-axis, a y-axis, and a z-axis are not limited to three axes on an orthogonal coordinate system, but may be interpreted in a broad sense including the three axes. For example, the x-axis, the y-axis, and the z-axis may be perpendicular to one another, or may represent different directions that are not perpendicular to one another.

As used herein, singular expressions may include plural expressions, unless the context clearly dictates otherwise. For example, the singular forms "a," "an," “one,” and "the" are intended to include the plural forms as well, unless the context clearly indicates otherwise.

In the present disclosure, terms such as "comprise(s)/comprising," "include(s)/including," and/or "has(have)/having" refer to that a feature or component described in the disclosure is present, and do not exclude the possibility that one or more other features or components may be added. Additionally, the terms “comprise(s)/comprising,” “include(s)/including,” “have/has/having,” or other similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof. Further, the use of “may” when describing embodiments of the present disclosure refers to “one or more embodiments of the present disclosure.

In the present disclosure, if (e.g., when) a part of a film, area, element, and/or the like is arranged over or on another part, it refers not only to an embodiment in which the part is directly on top of the other part, but also an embodiment in which one or more other films, areas, elements, and/or the like are located therebetween. In contrast, if (e.g., when) an element is referred to as being “directly on” another element, there are no intervening element present therebetween.

In the drawings, for convenience of description, the sizes of elements may be exaggerated or reduced. For example, the size and/or thickness of each element shown in the drawings are shown arbitrarily for convenience of description, and thus, embodiments of the present disclosure are not necessarily limited to shown.

In certain embodiments, in which the implementation is otherwise feasible, specific process sequences may be performed in a different order than described. For example, two processes described in succession may be performed substantially at the same time, or may be performed in an order opposite to the described order.

In the present disclosure, it will be understood that if (e.g., when) a layer, an area, or an element, and/or the like is referred to as being connected to another layer, area, or element, it may be directly or indirectly connected to the other layer, area, or element. For example, it will be understood in this disclosure that if (e.g., when) a layer, an area, or an element is referred to as being in contact with or electrically connected to another layer, area, or element, it may be directly or indirectly in contact with or electrically connected to the other layer, area, or element.

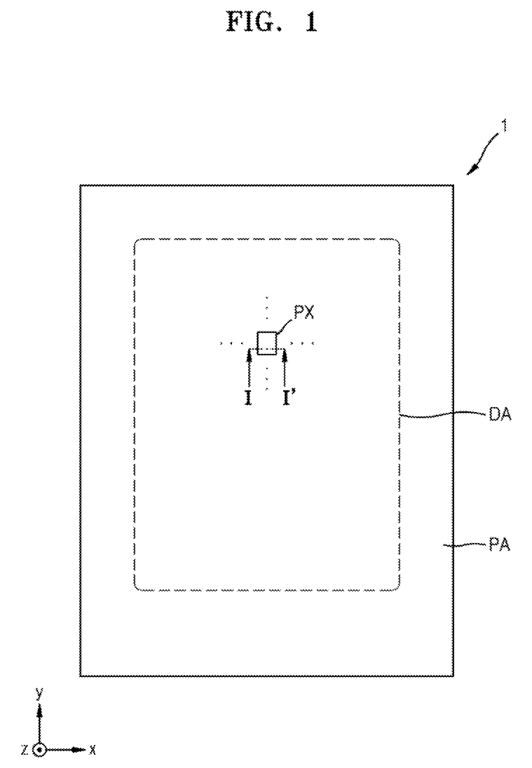

FIG. 1 is a schematic plan view of a display apparatus 1 according to one or more embodiments of the present disclosure.

Referring to FIG. 1, the display apparatus 1 according to one or more embodiments may include a display area DA and a peripheral area PA located outside (e.g., around) the display area DA. The display apparatus 1 may provide an image through an array of a plurality of pixels PX that are two-dimensionally arranged in the display area DA. Each of the pixels PX may include a display element, such as a light-emitting element. Each of the pixels PX may be to emit, for example, red light, green light, blue light, or white light (e.g., combined white light).

The peripheral area PA may be an area that does not provide an image and may completely or partially surround the display area DA. A driver and/or the like configured to provide electrical signals or power to pixel circuits for respective pixels PX may be arranged in the peripheral area PA. A pad may be located in the peripheral area PA. The pad may be electrically connected to electronic components or printed circuit boards.

FIG. 1 illustrates that the display area DA is a polygon (e.g., a rectangle) having a length in a first direction (e.g., x direction) that is smaller than a length in a second direction (e.g., y direction), but embodiments of the present disclosure are not limited thereto. In one or more embodiments, the display area DA may be a polygon (e.g., a rectangle) having a length in the second direction (e.g., the y direction) that is smaller than a length in the first direction (e.g., the x direction). FIG. 1 illustrates that the display area DA is approximately (e.g., substantially) rectangle, but embodiments of the present disclosure are not limited thereto. In one or more embodiments, the display area DA may have any one of one or more suitable shapes, such as an N-gon (N is a natural number greater than or equal to 3), a circle, and/or an ellipse. In one or more embodiments, the display area DA may be a polygon with rounded corners.

Hereinafter, the display apparatus 1 will be described as including an organic light-emitting diode OLED as the light-emitting element, but the display apparatus 1 of the disclosure is not limited thereto. In one or more embodiments, the display apparatus 1 may be a light-emitting display apparatus including an inorganic light-emitting diode, i.e., an inorganic light-emitting display apparatus. The inorganic light-emitting diode may include a PN junction diode including inorganic semiconductor-based materials. When a voltage is applied in a forward direction to the PN junction diode, holes and electrons are injected, and the energy generated by the recombination of the holes and electrons is converted into light energy, which may be to emit light of a certain color. The inorganic light-emitting diode may have a width of several to several hundred micrometers, and in one or more embodiments, the inorganic light-emitting diode may be referred to as a micro light-emitting diode. In one or more embodiments, the display apparatus 1 may be a quantum dot light-emitting display apparatus.

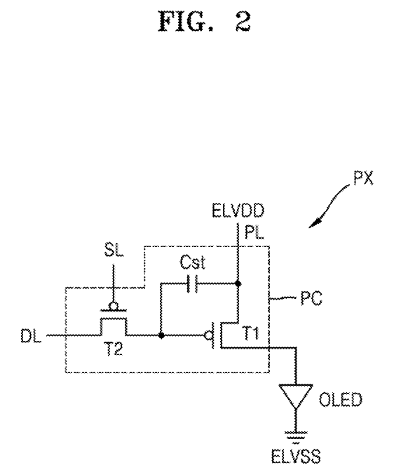

FIG. 2 is an equivalent circuit diagram of one of the pixels PX included in the display apparatus 1, according to one or more embodiments.

Each pixel PX may include a pixel circuit PC and a display element, such as an organic light-emitting diode OLED, electrically connected to the pixel circuit PC. The pixel circuit PC may include a first thin film transistor T1, a second thin film transistor T2, and a storage capacitor Cst. Each pixel PX may be to emit light, such as red light, green light, blue light, or white light (e.g., combined white light) via the organic light-emitting diode OLED.

The second thin film transistor T2 may be a switching thin film transistor, electrically connected to a scan line SL and a data line DL, and may be to transmit a data voltage input from the data line DL to the first thin film transistor T1 based on a switching voltage input from the scan line SL. The storage capacitor Cst may be electrically connected to the second thin film transistor T2 and a driving voltage line PL, and store a voltage corresponding to the difference between a voltage received from the second thin film transistor T2 and a first power supply voltage ELVDD supplied to the driving voltage line PL.

The first thin film transistor T1 may be a driving thin film transistor electrically connected to the driving voltage line PL and the storage capacitor Cst, and may control a driving current flowing from the driving voltage line PL to the organic light-emitting diode OLED in response to a value of the voltage stored in the storage capacitor Cst. The organic light-emitting diode OLED may be to emit light with a certain brightness depending on the driving current. A common electrode (e.g., cathode) of the organic light-emitting diode OLED may be supplied with a second power supply voltage ELVSS.

FIG. 2 illustrates that the pixel circuit PC includes two thin film transistors and one storage capacitor, but embodiments of the present disclosure are not limited thereto. The number of thin film transistors and the number of storage capacitors may vary depending on the design of the pixel circuit PC. For example, in one or more embodiments, the pixel circuit PC may include three, four, five or more thin film transistors.

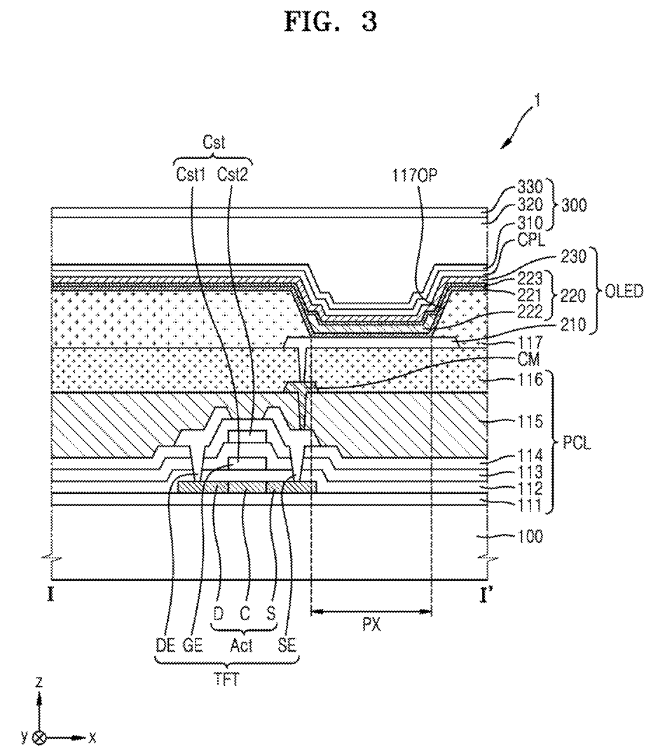

FIG. 3 is a schematic cross-sectional view of the display apparatus 1, taken along the line I-I' of FIG. 1, according to one or more embodiments.

Referring to FIG. 3, the display apparatus 1 may include a stacked structure of a substrate 100, a pixel circuit layer PCL, the organic light-emitting diode OLED, a capping layer CPL, and an encapsulating layer 300.

The substrate 100 may include glass, a metal, or a polymer resin. The polymer resin may include polyethersulfone, polyacrylate, polyetherimide, polyethylene naphthalate, polyethylene terephthalate, polyphenylene sulfide, polyarylate, polyimide, polycarbonate, cellulose acetate propionate, or a mixture thereof. In one or more embodiments, the substrate 100 may have a multi-layer structure including at least two base layers each including one or more of the polymer resins described above and an inorganic layer arranged between the base layers.

The pixel circuit layer PCL may be arranged on the substrate 100. The pixel circuit layer PCL may include a thin film transistor TFT, a buffer layer 111 arranged below and/or above components of the thin film transistor TFT, a first gate insulating layer 112, a second gate insulating layer 113, an interlayer insulating layer 114, a first planarization insulating layer 115, and a second planarization insulating layer 116.

The buffer layer 111 may be arranged on the substrate 100. The buffer layer 111 may reduce or block the penetration of foreign substances, moisture, and/or external air from under the substrate 100 and provide a flat surface on the substrate 100. The buffer layer 111 may include an inorganic insulating material such as silicon oxide, silicon oxynitride, and/or silicon nitride, and may be provided in a single-layer or multi-layer structure each including one or more of the aforementioned materials.

The thin film transistor TFT may be arranged on the buffer layer 111. The thin film transistor TFT may include a semiconductor layer Act, a gate electrode GE, a drain electrode DE, and a source electrode SE.

In one or more embodiments, the semiconductor layer Act may include polysilicon (poly-Si). In one or more embodiments, the semiconductor layer Act may include amorphous silicon (a-Si), an oxide semiconductor, an organic semiconductor, and/or the like. The semiconductor layer Act may include a channel region C, and a drain region D and a source region S respectively arranged on opposite sides of the channel region C. The channel region C may overlap the gate electrode GE.

The gate electrode GE may include a low-resistance metal material. The gate electrode GE may include a conductive material such as molybdenum (Mo), aluminum (Al), copper (Cu), titanium (Ti), and/or the like, and may be provided as a single-layer or a multi-layer structure each including one or more of the aforementioned materials.

The first gate insulating layer 112 between the semiconductor layer Act and the gate electrode GE may include an inorganic insulating material, such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), and/or zinc oxide (ZnOₓ). Zinc oxide (ZnOₓ) may be zinc oxide (ZnO) and/or zinc peroxide (ZnO₂).

The second gate insulating layer 113 may cover the gate electrode GE. Similar to the first gate insulating layer 112, the second gate insulating layer 113 may include an inorganic insulating material such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), and/or zinc oxide (ZnOₓ). Zinc oxide (ZnOₓ) may be zinc oxide (ZnO) and/or zinc peroxide (ZnO₂).

An upper electrode Cst2 of the storage capacitor Cst may be arranged on the second gate insulating layer 113. The upper electrode Cst2 of the storage capacitor Cst may overlap the gate electrode GE. The storage capacitor Cst may include the gate electrode GE and the upper electrode Cst2 of the storage capacitor Cst overlapping the gate electrode GE. The second gate insulating layer 113 may be arranged between the gate electrode GE and the upper electrode Cst2 of the storage capacitor Cst. For example, the gate electrode GE may function as a lower electrode Cst1 of the storage capacitor Cst.

In one or more embodiments, the storage capacitor Cst and the thin film transistor TFT may overlap each other. In one or more embodiments, the storage capacitor Cst may be not to overlap the thin film transistor TFT.

The upper electrode Cst2 of the storage capacitor Cst may include aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), and/or copper (Cu), and may be a single-layer or a multi-layer structure each including one or more of the aforementioned materials.

The interlayer insulating layer 114 may cover the upper electrode Cst2 of the storage capacitor Cst. The interlayer insulating layer 114 may include silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), and/or zinc oxide (ZnOₓ). Zinc oxide (ZnOx) may be zinc oxide (ZnO) and/or zinc peroxide (ZnO₂). The interlayer insulating layer 114 may be a single-layer or a multi-layer structure each including one or more of the aforementioned inorganic insulating materials.

The drain electrode DE and source electrode SE may each be arranged on the interlayer insulating layer 114. The drain electrode DE and the source electrode SE may be electrically connected to the drain region D and the source region S, respectively, through contact holes formed in the insulating layers (i.e., the first gate insulating layer 112, the second gate insulating layer 113, and the interlayer insulating layer 114) arranged below the drain electrode DE and the source electrode SE. The drain electrode DE and source electrode SE may each include a material with good or suitable electrical conductivity. The drain electrode DE and the source electrode SE may each include a conductive material including molybdenum (Mo), aluminum (Al), copper (Cu), titanium (Ti), and/or the like, and may be provided as a single-layer or a multi-layer structure each including one or more of the aforementioned materials. In one or more embodiments, the drain electrode DE and the source electrode SE may each have a multi-layer structure of Ti/Al/Ti.

The first planarization insulating layer 115 may cover the drain electrode DE and the source electrode SE. The first planarization insulating layer 115 may include an organic insulating material such as a general-purpose polymer such as polymethylmethacrylate (PMMA) or polystyrene (PS), a polymer derivative having a phenol group, an acrylic polymer, an imide polymer, an aryl ether polymer, an amide polymer, a fluorinated polymer, a p-xylene polymer, a vinyl alcohol polymer, or a blend thereof.

The second planarization insulating layer 116 may be arranged on the first planarization insulating layer 115. The second planarization insulating layer 116 may include a same material as that of the first planarization insulating layer 115, and may include an organic insulating material such as a general-purpose polymer such as polymethylmethacrylate (PMMA) or polystyrene (PS), a polymer derivative having a phenol group, an acrylic polymer, an imide polymer, an aryl ether polymer, an amide polymer, a fluorinated polymer, a p-xylene polymer, a vinyl alcohol polymer, or a blend thereof.

The organic light-emitting diode OLED may be arranged on the pixel circuit layer PCL of the above-described structure as a display element (i.e., a light-emitting element). The organic light-emitting diode OLED may include a stacked structure of a pixel electrode 210, an intermediate layer 220, and an opposite electrode 230. The organic light-emitting diodes OLED may be to emit, for example, red light, green light, or blue light, or may be to emit red light, green light, blue light, or white light (e.g., combined white light). The organic light-emitting diodes OLED may be to emit light through an emission area, which may be defined as pixels PX.

The pixel electrode 210 of the organic light-emitting diode OLED may be electrically connected to the thin film transistor TFT through contact holes formed in the second planarization insulating layer 116 and the first planarization insulating layer 115 and a contact metal CM arranged on the first planarization insulating layer 115. For example, the pixel electrode 210 may be arranged on the substrate 100.

In one or more embodiments, the pixel electrode 210 may include a conductive oxide such as indium tin oxide (ITO), indium zinc oxide (IZO), zinc oxide (ZnOₓ), indium oxide (In₂O₃), indium gallium oxide (IGO), and/or aluminum zinc oxide (AZO). In one or more embodiments, the pixel electrode 210 may include a reflective layer including silver (Ag), magnesium (Mg), aluminum (Al), platinum (Pt), palladium (Pd), gold (Au), nickel (Ni), neodymium (Nd), iridium (Ir), chromium (Cr), an alloy thereof, or a compound thereof.

A bank layer 117 having an opening 117OP exposing a central portion of the pixel electrode 210 is arranged on the pixel electrode 210. The bank layer 117 may include an organic insulating material and/or an inorganic insulating material. The opening 117OPmay define the emission area of light emitted from the organic light-emitting diode OLED. For example, a size/width of the opening 117OP may correspond to a size/width of the emission area. Therefore, a size and/or width of the pixel PX may depend on the size and/or width of the opening 117OP of the corresponding bank layer 117.

The intermediate layer 220 may include an emission layer 222 formed to correspond to the pixel electrode 210. In one or more embodiments, the emission layer 222 may include a high-molecular weight organic material and/or a low-molecular weight organic material, which emit light of certain color. In one or more embodiments, the emission layer 222 may include an inorganic light-emitting material or quantum dots. For example, the intermediate layer 220 may be arranged on the pixel electrode 210 and may be to emit light.

In one or more embodiments, the intermediate layer 220 may include a first functional layer 221 and a second functional layer 223 respectively arranged below and above the emission layer 222. The first functional layer 221 may include, for example, a hole transport layer (HTL) or a hole transport layer (HTL) and a hole injection layer (HIL). The second functional layer 223 may be a component arranged on the emission layer 222 and may include an electron transport layer (ETL) and/or an electron injection layer (EIL). The first functional layer 221 and/or the second functional layer 223 may be a common layer formed to entirely cover the substrate 100, similar to the opposite electrode 230 described below.

The opposite electrode 230 may be arranged on the pixel electrode 210 and may overlap the pixel electrode 210. The opposite electrode 230 may be arranged on the intermediate layer 220. In one or more embodiments, the opposite electrode 230 may include a conductive material with a low work function. For example, in one or more embodiments, the opposite electrode 230 may include a transparent layer (or a semitransparent layer) including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), or an alloy thereof. In one or more embodiments, the opposite electrode 230 may further include a layer including ITO, IZO, ZnO, or In₂O₃ on the transparent layer (or the semitransparent layer) including one or more of the above-mentioned metal materials. The opposite electrode 230 may be formed integrally to cover the entire substrate 100.

The capping layer CPL may be arranged on the organic light-emitting diode OLED and may cover the organic light-emitting diode OLED. For example, the capping layer CPL may be arranged on the opposite electrode 230. In one or more embodiments, the capping layer CPL may have a higher refractive index than the opposite electrode 230.

The encapsulating layer 300 may be arranged on the capping layer CPL. The encapsulating layer 300 may be arranged on the organic light-emitting diode OLED and may cover the organic light-emitting diode OLED. The encapsulating layer 300 may include at least one inorganic encapsulating layer and at least one organic encapsulating layer, and as an example, FIG. 3 illustrates that the encapsulating layer 300 includes a first inorganic encapsulating layer 310, an organic encapsulating layer 320, and a second inorganic encapsulating layer 330 that are sequentially stacked (e.g., in the stated order).

Each of the first inorganic encapsulating layer 310 and the second inorganic encapsulating layer 330 may independently include one or more inorganic materials selected from among aluminum oxide, titanium oxide, tantalum oxide, hafnium oxide, zinc oxide, silicon oxide, silicon nitride, and silicon oxynitride.

The organic encapsulating layer 320 may include a polymer-based material. The polymer-based material may include acrylic resin, epoxy resin, polyimide, polyethylene, and/or the like. In one or more embodiments, the organic encapsulating layer 320 may include acrylate. The organic encapsulating layer 320 may be formed by curing a monomer or applying a polymer. The organic encapsulating layer 320 may have transparency.

In one or more embodiments, a touch sensor layer may be further arranged on the encapsulating layer 300, and an optical function layer may be further arranged on the touch sensor layer. The touch sensor layer may obtain coordinate information based on an external input, such as a touch event. The optical functional layer may reduce the reflectivity of light (external light) incident from the outside toward the display apparatus 1 and/or improve the color purity of light emitted from the display apparatus 1. In one or more embodiments, the optical functional layer may include a retarder and/or a polarizer. The retarder may be of film type (kind) or liquid crystal coating type (kind), and may include a λ/2 retarder and/or a λ/4 retarder. The polarizer may also be of film type (kind) or liquid crystal coating type (kind). The film type (kind) may include a stretchable synthetic resin film, and the liquid crystal coating type (kind) may include liquid crystals arranged in a set or predetermined array. The retarder and the polarizer may each further include a protective film.

An adhesive layer may be arranged between the touch sensor layer and the optical function layer. The adhesive layer may be formed using any material suitable in the related art, without limitation. In one or more embodiments, the adhesive layer may be a pressure sensitive adhesive (PSA).

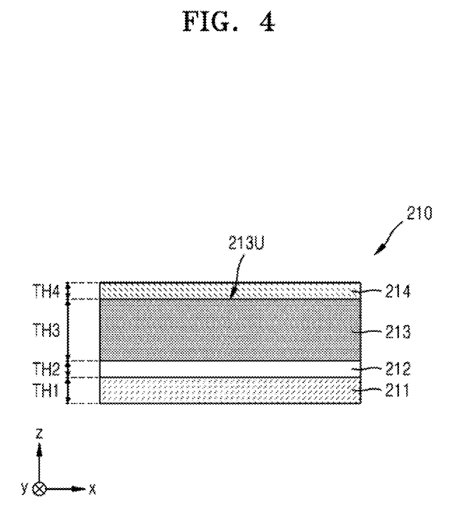

FIG. 4 is a schematic cross-sectional view of the pixel electrode 210 of the display apparatus 1 according to one or more embodiments of the present disclosure.

Referring to FIGS. 3 and 4, the pixel electrode 210 may include a lower transparent conductive oxide layer 211, a getter layer 212, a reflective layer 213, and an upper transparent conductive oxide layer 214.

The lower transparent conductive oxide layer 211, the getter layer 212, the reflective layer 213, and the upper transparent conductive oxide layer 214 may be sequentially stacked (e.g., in the stated order). For example, the getter layer 212 may be arranged on the lower transparent conductive oxide layer 211, the reflective layer 213 may be arranged on the getter layer 212, and the upper transparent conductive oxide layer 214 may be arranged on the reflective layer 213. For example, the lower transparent conductive oxide layer 211 may be arranged on the substrate 100, the reflective layer 213 may be arranged on the lower transparent conductive oxide layer 211, the upper transparent conductive oxide layer 214 may be arranged on the reflective layer 213, and the getter layer 212 may be arranged between the lower transparent conductive oxide layer 211 and the reflective layer 213.

The lower transparent conductive oxide layer 211 may be arranged between the substrate 100 and the getter layer 212. For example, in one or more embodiments, the lower transparent conductive oxide layer 211 may be arranged between the second planarization insulating layer 116 and the getter layer 212.

The lower transparent conductive oxide layer 211 may include, for example, at least one of indium tin oxide (ITO), indium zinc oxide (IZO), zinc oxide (ZnOₓ), indium oxide (In₂O₃), indium gallium oxide (IGO), indium gallium zinc oxide (IGZO), gallium zinc oxide (GZO), or aluminum zinc oxide (AZO).

The getter layer 212 may be arranged below the reflective layer 213. The getter layer 212 may be arranged between the lower transparent conductive oxide layer 211 and the reflective layer 213. For example, the getter layer 212 may be arranged between the substrate 100 and the reflective layer 213. For example, a distance between the substrate 100 and the getter layer 212 may be smaller than a distance between the substrate 100 and the reflective layer 213. For example, a distance between the intermediate layer 220 and the getter layer 212 may be greater than a distance between the intermediate layer 220 and the reflective layer 213. For example, a distance between the opposite electrode 230 and the getter layer 212 may be greater than a distance between the opposite electrode 230 and the reflective layer 213.

The getter layer 212 may be a layer that absorbs (or captures) gas generated from the substrate 100 and/or the pixel circuit layer PCL. The getter layer 212 functions as a getter that absorbs gas, thereby reducing or preventing pixel shrinkage. The getter layer 212 may include a material that absorbs (or captures) gas. For example, the getter layer 212 may include at least one of ytterbium (Yb) or magnesium (Mg).

The reflective layer 213 may be arranged above the getter layer 212. The reflective layer 213 may be arranged between the getter layer 212 and the upper transparent conductive oxide layer 214. For example, the reflective layer 213 may be arranged between the getter layer 212 and the intermediate layer 220. For example, the reflective layer 213 may be arranged between the getter layer 212 and the opposite electrode 230.

The reflective layer 213 may be a layer that reflects light in a front direction (e.g., z direction) so that light emitted from the emission layer 222 is not lost in the substrate direction (e.g., -z direction). For example, light may be reflected from an upper surface213U of the reflective layer 213. The upper surface 213U of the reflective layer 213 may be a surface facing the opposite electrode 230. The upper surface 213U of the reflective layer 213 may be a surface facing the upper transparent conductive oxide layer 214. The reflective layer 213 may include, for example, silver (Ag), magnesium (Mg), aluminum (Al), platinum (Pt), palladium (Pd), gold (Au), nickel (Ni), neodymium (Nd), iridium (Ir), chromium (Cr), or an alloy thereof. For example, the reflective layer 213 may include at least one of silver (Ag), magnesium (Mg), aluminum (Al), platinum (Pt), palladium (Pd), gold (Au), nickel (Ni), neodymium (Nd), iridium (Ir), or chromium (Cr).

In the case of a comparative example in which a getter layer is arranged above an upper surface of a reflective layer, light reflected from the upper surface of the reflective layer is absorbed by the getter layer, thereby reducing light efficiency of a display apparatus. In contrast, in one or more embodiments of the present disclosure, because the getter layer 212 is arranged below the reflective layer 213, the getter layer 212 does not affect the light reflection of the reflective layer 213, and pixel shrinkage may also be reduced or prevented. Accordingly, embodiments of the present disclosure may provide a high-quality image by reducing or preventing pixel shrinkage while having superior light efficiency.

In the case of a comparative example in which an opposite electrode includes a getter layer including a material that absorbs (or captures) gas (e.g., ytterbium (Yb) and/or magnesium (Mg)), as a thickness of the getter layer included in the opposite electrode increases, light may be absorbed in the opposite electrode and the light efficiency may decrease. In contrast, in one or more embodiments of the present disclosure, because the pixel electrode 210 includes the getter layer 212, and in particular, the getter layer 212 is arranged below the reflective layer 213, the display apparatus 1 may provide a high-quality image by reducing or preventing pixel shrinkage while having superior light efficiency.

The upper transparent conductive oxide layer 214 may be arranged between the reflective layer 213 and the intermediate layer 220. For example, the upper transparent conductive oxide layer 214 may be arranged between the reflective layer 213 and the opposite electrode 230.

The upper transparent conductive oxide layer 214 may include, for example, at least one of indium tin oxide (ITO), indium zinc oxide (IZO), zinc oxide (ZnOₓ), indium oxide (In₂O₃), indium gallium oxide (IGO), indium gallium zinc oxide (IGZO), gallium zinc oxide (GZO), or aluminum zinc oxide (AZO).

A thickness TH2 of the getter layer 212 may be smaller than a thickness TH3 of the reflective layer 213. For example, the thickness TH2 of the getter layer 212 may be in a range of (from) about 5% to about 15% of the thickness TH3 of the reflective layer 213. When the thickness TH2 of the getter layer 212 is smaller than about 5% of the thickness TH3 of the reflective layer 213, the pixel may shrink. When the thickness TH2 of the getter layer 212 exceeds the above range, an electrical reliability of the pixel electrode 210 may deteriorate. For example, if (e.g., when) the thickness TH3 of the reflective layer 213 is about 800 angstroms (Å), the thickness of the getter layer 212 may be about 60 Å.

In one or more embodiments, the thickness TH2 of the getter layer 212 may be smaller than a thickness TH1 of the lower transparent conductive oxide layer 211. In one or more embodiments, the thickness TH2 of the getter layer 212 may be greater than a thickness TH4 of the upper transparent conductive oxide layer 214. For example, if (e.g., when) the thickness TH3 of the reflective layer 213 is about 800 Å, the thickness TH2 of the getter layer 212 may be about 60 Å, the thickness TH1 of the lower transparent conductive oxide layer 211 may be about 115 Å, and the thickness TH4 of the upper transparent conductive oxide layer 214 may be about 50 Å. In one or more embodiments, the thickness TH2 of the getter layer 212 may be substantially equal to or greater than the thickness TH1 of the lower transparent conductive oxide layer 211. In one or more embodiments, the thickness TH2 of the getter layer 212 may be substantially equal to or less than the thickness TH4 of the upper transparent conductive oxide layer 214.

A method of manufacturing the display apparatus 1 according to one or more embodiments may include forming the pixel electrode 210 by sequentially stacking the lower transparent conductive oxide layer 211, the getter layer 212, the reflective layer 213, and the upper transparent conductive oxide layer 214 on the substrate 100, forming the intermediate layer 220 including the emission layer 222 on the pixel electrode 210, and forming the opposite electrode 230 on the intermediate layer 220. The getter layer 212 may include a material that absorbs (or captures) a gas, such as, for example, ytterbium (Yb) and/or magnesium (Mg). For example, after the pixel electrode 210 is formed on the substrate 100, the intermediate layer 220 may be formed on the pixel electrode 210, and after the intermediate layer 220 is formed, the opposite electrode 230 may be formed on the intermediate layer 220.

In one or more embodiments, each of the lower transparent conductive oxide layer 211 and the upper transparent conductive oxide layer 214 may be formed by a sputtering process and/or a chemical vapor deposition (CVD) process.

In one or more embodiments, the getter layer 212 may be formed by a sputtering process. In one or more embodiments, the reflective layer 213 may be formed by a sputtering process. Because the getter layer 212 is formed by a same sputtering process as the reflective layer 213, a separate process method is not needed or required, so the manufacturing cost and/or manufacturing time may be reduced.

The display apparatus 1 according to one or more embodiments may be applied to any suitable electronic apparatus. An electronic apparatus according to one or more embodiments may include the display apparatus 1 described above, and may further include a module or an apparatus having additional functions in addition to the display apparatus 1.

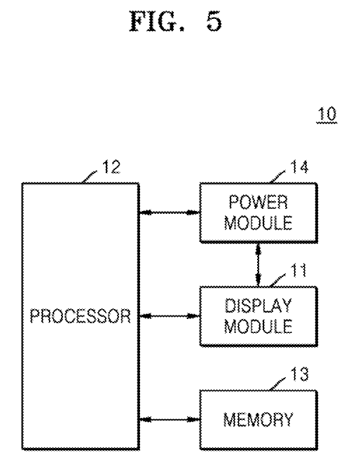

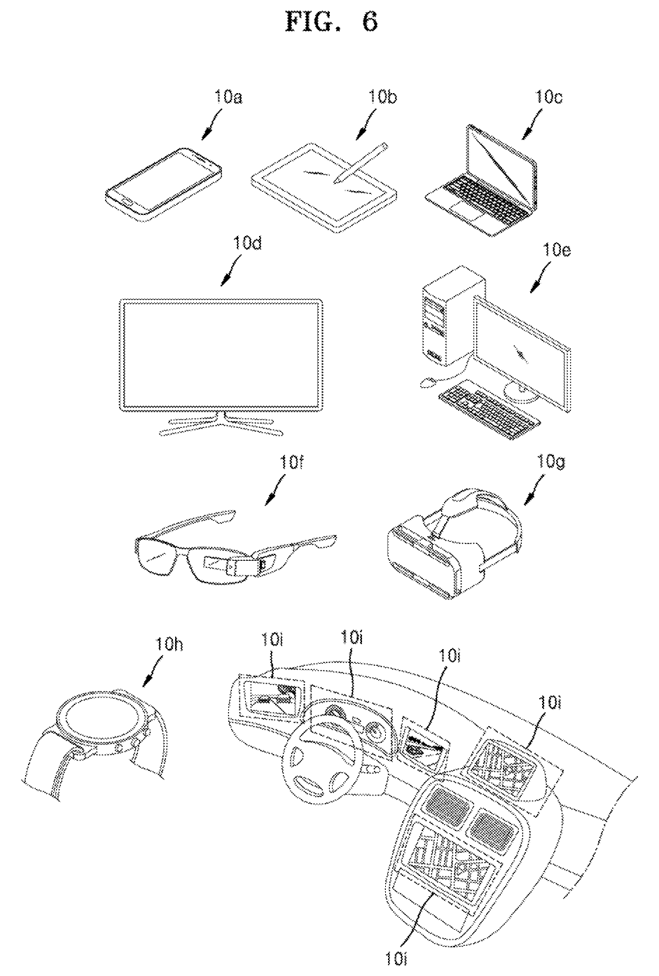

FIG. 5 is a block diagram of an electronic apparatus 10 according to one or more embodiments of the present disclosure. FIG. 6 illustrates schematic views of the electronic apparatus 10 according to various embodiments of the present disclosure.

Referring to FIG. 5, an electronic apparatus 10 according to one or more embodiments may include a display module 11, a processor 12, a memory 13, and a power module 14.

The display module 11 may include the display apparatus 1 (see FIG. 3) according to one or more embodiments.

The processor 12 may include at least one of a central processing unit (CPU), an application processor (AP), a graphic processing unit (GPU), a communication processor (CP), an image signal processor (ISP), or a controller.

The memory 13 may store data information necessary for an operation of the processor 12 and/or the display module 11. When the processor 12 executes an application stored in the memory 13, an image data signal and/or an input control signal may be transmitted to the display module 11, and the display module 11 may process the received signal and output image information through a display screen.

The power module 14 may include a power supply module, such as a power adapter or a battery device, and a power conversion module that converts power supplied by the power supply module to generate power desired or required for the operation of the electronic apparatus 10.

At least one of the components of the electronic apparatus 10 described above may be included in the display apparatus included in the display module 11. Additionally, some of the individual modules functionally included within a module may be included in the display apparatus, while others may be provided separately from the display apparatus. For example, in one or more embodiments, the display apparatus may include (e.g., be) the display module 11, and the processor 12, the memory 13 and the power module 14 may be provided in the form of other apparatuses within the electronic apparatus 10 other than the display apparatus.

Referring to FIG. 6, one or more suitable electronic apparatuses including the display apparatus 1 (see FIG. 3) according to one or more embodiments may include not only image display electronic apparatuses such as a smart phone 10a, a tablet PC 10b, a laptop 10c, a TV 10d, and/or a desk monitor 10e, but also wearable electronic apparatuses including display modules such as smart glasses 10f, a head mounted display 10g, a smart watch 10h, and/or the like, and vehicle electronic apparatuses 10i including display modules such as a dashboard, a center fascia, a CID (Center Information Display) arranged on the dashboard, a room mirror display, and/or the like.

The display apparatus and an electronic apparatus including the same, according to one or more embodiments, may implement a high-quality image by reducing or preventing pixel shrinkage through the inclusion of a getter layer configured to absorb gas. For example, the getter layer, positioned beneath the reflective layer within the pixel electrode structure, plays a role in mitigating the effects of gas emissions originating from the substrate or pixel circuit layer—factors that may contribute to pixel degradation over time. By locating the getter layer below the reflective layer, the design avoids interference with light reflection, thereby preserving or enhancing light efficiency. Furthermore, the enhanced thickness relationships among the getter layer, reflective layer, and transparent conductive oxide layers contribute to both electrical reliability and optical performance. These structural and material innovations collectively support the development of display apparatuses that are not only visually superior but also more durable and reliable across a range of electronic apparatuses. The above-described effects and benefits are examples, and the scope of the disclosure is not limited by these effects and benefits.

In the context of the present application and unless otherwise defined, the terms "use," "using," and "used" may be considered synonymous with the terms "utilize," "utilizing," and "utilized," respectively.

As utilized herein, the terms “substantially,” “about,” or similar terms are used as terms of approximation and not as terms of degree, and are intended to account for the inherent deviations in measured or calculated values that would be recognized by those of ordinary skill in the art. “About” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ± 30%, ± 20%, ± 10%, or ± 5% of the stated value. Also, it should be understood that, even if the terms “about,” “approximately,” or “substantially” are not expressly recited in a given element (e.g., a claim element), the scope of such element is intended to include variations that are insubstantial or within the understanding of one of ordinary skill in the art. For example, numerical values and ranges provided herein are intended to include tolerances and measurement uncertainties that would be recognized by those skilled in the art, and the elements (e.g., claim elements) should be construed accordingly to encompass such equivalents.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this disclosure, including the claims, to expressly recite any sub-range subsumed within the ranges expressly recited herein.

The display apparatus, the display module, the electronic apparatus, the display apparatus-manufacturing apparatus, or any other relevant apparatuses/devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random-access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

The example embodiments have been described with reference to one or more embodiments shown in the drawings, but they are merely examples, and one of ordinary skill in the art will understand that one or more suitable modifications and variations of the embodiment are possible therefrom. Therefore, the protection scope of the present disclosure should be determined by the appended claims and equivalents thereof.

What is claimed is:

1. A display apparatus, comprising:
a substrate;
a pixel electrode comprising a lower transparent conductive oxide layer on the substrate, a reflective layer on the lower transparent conductive oxide layer, an upper transparent conductive oxide layer on the reflective layer, and a getter layer between the lower transparent conductive oxide layer and the reflective layer;
an intermediate layer on the pixel electrode and comprising an emission layer; and
an opposite electrode on the intermediate layer,
wherein the getter layer comprises at least one of ytterbium or magnesium.

2. The display apparatus of claim 1, wherein
the lower transparent conductive oxide layer is between the substrate and the getter layer, and
the upper transparent conductive oxide layer is between the reflective layer and the intermediate layer.

3. The display apparatus of claim 1, wherein
a distance between the intermediate layer and the getter layer is greater than a distance between the intermediate layer and the reflective layer.

4. The display apparatus of claim 1, wherein
a thickness of the getter layer is smaller than a thickness of the reflective layer.

5. The display apparatus of claim 4, wherein
the thickness of the getter layer is in a range from 5% to 15% of the thickness of the reflective layer.

6. The display apparatus of claim 1, wherein
a thickness of the getter layer is smaller than a thickness of the lower transparent conductive oxide layer.

7. The display apparatus of claim 1, wherein
the reflective layer comprises at least one of silver, magnesium, aluminum, platinum, palladium, gold, nickel, neodymium, iridium, or chromium.

8. The display apparatus of claim 1, wherein
each of the lower transparent conductive oxide layer and the upper transparent conductive oxide layer comprises at least one of indium tin oxide, indium zinc oxide, zinc oxide, indium oxide, indium gallium oxide, indium gallium zinc oxide, gallium zinc oxide, or aluminum zinc oxide.

9. An electronic apparatus comprising:
a display module comprising a display apparatus; and
a processor configured to provide an image data signal and an input control signal to the display module,
wherein the display apparatus comprises:
a substrate;
a pixel electrode comprising a lower transparent conductive oxide layer on the substrate, a reflective layer on the lower transparent conductive oxide layer, an upper transparent conductive oxide layer on the reflective layer, and a getter layer between the lower transparent conductive oxide layer and the reflective layer;
an intermediate layer on the pixel electrode and comprising an emission layer; and
an opposite electrode on the intermediate layer, and
wherein the getter layer comprises at least one of ytterbium or magnesium.

10. The electronic apparatus of claim 9, wherein
the lower transparent conductive oxide layer is between the substrate and the getter layer, and
the upper transparent conductive oxide layer is between the reflective layer and the intermediate layer.

11. The electronic apparatus of claim 9, wherein
a thickness of the getter layer is smaller than a thickness of the reflective layer.

12. The electronic apparatus of claim 11, wherein
the thickness of the getter layer is in a range from 5% to 15% of the thickness of the reflective layer.

13. The electronic apparatus of claim 9, wherein
a thickness of the getter layer is smaller than a thickness of the lower transparent conductive oxide layer.

14. The electronic apparatus of claim 9, wherein
the electronic apparatus is any one selected from among a mobile phone, a tablet personal computer, a laptop, a television, a desk monitor, smart glasses, a head-mounted display, a smart watch, and a vehicle electronic apparatus.

15. A method, comprising:
on a substrate, sequentially stacking a lower transparent conductive oxide layer, a getter layer, a reflective layer, and an upper transparent conductive oxide layer, to form a pixel electrode;
forming an intermediate layer comprising an emission layer on the pixel electrode; and
forming an opposite electrode on the intermediate layer,
wherein the getter layer comprises at least one of ytterbium or magnesium, and
wherein the method is a method of manufacturing a display apparatus.

16. The method of claim 15, wherein
the getter layer is between the lower transparent conductive oxide layer and the reflective layer,
the lower transparent conductive oxide layer is between the substrate and the getter layer, and
the upper transparent conductive oxide layer is between the reflective layer and the intermediate layer.

17. The method of claim 15, wherein
the getter layer is formed by a sputtering process.

18. The method of claim 15, wherein
a thickness of the getter layer is formed to be smaller than a thickness of the reflective layer.

19. The method of claim 18, wherein
the thickness of the getter layer is in a range from 5% to 15% of the thickness of the reflective layer.

20. The method of claim 15, wherein
a thickness of the getter layer is formed to be smaller than a thickness of the lower transparent conductive oxide layer.
